(19) United States
(12) Patent Application Publication
(10) Pub. No.: US 2008/0099862 A1
(43) Pub. Date: May 1, 2008

(54) Physical quantity sensor and method for manufacturing the same

(75) Inventors: Tetsuo Fujii, Toyohashi-city (JP); Hiroaki Himi, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/902,985

(22) Filed: Sep. 27, 2007

(30) Foreign Application Priority Data
Oct. 30, 2006 (JP) 2006-294156
Jun. 4, 2007 (JP) 2007-148073

(51) Int. Cl. H01L 29/84; H01L 21/50

(52) U.S. Cl. 257/417; 438/50; 257/E21.705; 257/E29.324

(57) ABSTRACT

A method for manufacturing a physical quantity sensor includes: forming a sensor element in a first wafer; stacking a support substrate, a connection layer and a cap layer in this order so that a second wafer is prepared; bonding the cap layer of the second wafer to the first wafer in such a manner that the sensor element is disposed in a space between the first wafer and the second wafer; removing the support substrate and the connection layer from the second wafer; and dividing the first wafer together with the cap layer into a plurality of chips so that a plurality of physical quantity sensors is formed.

### CROSS REFERENCE TO RELATED APPLICATIONS

This application is based on Japanese Patent Applications No. 2006-294156 filed on Oct. 30, 2006, and No. 2007-148073 filed on Jun. 4, 2007, the disclosures of which are incorporated herein by reference.

### FIELD OF THE INVENTION

The present invention relates to a physical quantity sensor and a method for manufacturing the same.

### BACKGROUND OF THE INVENTION

The manufacturing method of the semiconductor dynamical amount sensor able to prevent mixture of water and a foreign substance to the movable portion, etc. by covering the movable portion with the cap is formerly proposed. For example, JP-A-2004-333133 discloses a method in which a glass substrate and a silicon substrate are stuck to a silicon substrate constituting the movable portion of the acceleration sensor in a wafer state as it is. In this method, the silicon substrate constituting the movable portion is thus covered with the glass substrate or the silicon substrate, and is further dicing-cut and is thereby divided in a chip unit so that the semiconductor dynamical amount sensor covered with the cap is manufactured.

However, the glass substrate or the silicon substrate for constructing the cap must be held in the wafer state, and a thickness of about 300 to 800 μm is required so as not to cause a crack. Therefore, a problem exists in that a long processing time for forming a hole portion for making electric connection with a circuit portion of the semiconductor dynamical amount sensor is required with respect to the glass substrate or the silicon substrate for constructing the cap. Further, since the glass substrate or the silicon substrate for constructing the cap cannot be thinly formed, a problem also exists in that no thin formation of the semiconductor dynamical amount sensor required and desired in recent years is satisfied.

Therefore, JP-A-H10-19924 proposes a structure in which a polyimide resin film is used and the cap is constructed by sticking this polyimide resin film to the semiconductor dynamical amount sensor forming the movable portion therein.

However, when the interior covered with the cap, i.e., a portion for forming the movable portion is set to a vacuum, the polyimide resin film is flexed and there is a problem in maintenance of a vacuum degree. In contrast to this, when the vacuum degree is intended to be maintained, the polyimide resin film must be set to a thickness of a certain degree. Therefore, a problem exists in that no thin formation of the semiconductor dynamical amount sensor required and desired in recent years can be finally satisfied.

Thus, it is required to thinly form the semiconductor dynamical amount sensor by setting the cap so as to be thinly formed, and easily maintain the vacuum degree.

### SUMMARY OF THE INVENTION

In view of the above-described problem, it is an object of the present disclosure to provide a physical quantity sensor and a method for manufacturing a physical quantity sensor.

According to a first aspect of the present disclosure, a physical quantity sensor includes: a semiconductor substrate; a sensor element disposed in the substrate; and a cap layer disposed on the substrate so that a space between the cap layer and the substrate is provided. The cap layer is directly bonded to the substrate, and the cap layer faces the sensor element in such a manner that the sensor element is disposed in the space. Further, the vacuum in the space is maintained, and the thickness of the sensor is reduced.

The above sensor has no adhesive between the first and second wafers. Thus, penetration of the adhesive to the sensor element is not occurred in the above sensor.

According to a second aspect of the present disclosure, a method for manufacturing a physical quantity sensor includes: forming a sensor element in a first wafer; stacking a support substrate, a connection layer and a cap layer in this order so that a second wafer is prepared; bonding the cap layer of the second wafer to the first wafer in such a manner that the sensor element is disposed in a space between the first wafer and the second wafer; removing the support substrate and the connection layer from the second wafer; and dividing the first wafer together with the cap layer into a plurality of chips so that a plurality of physical quantity sensors is formed.

The above method provides to maintain vacuum in the space and to reduce thickness of the sensor.

### BRIEF DESCRIPTION OF THE DRAWINGS

The above and other objects, features and advantages of the present invention will become more apparent from the following detailed description made with reference to the accompanying drawings. In the drawings:

FIGS. 1A to 1F are cross-sectional views showing a manufacturing process of a semiconductor dynamical amount sensor in a first embodiment mode;

FIG. 2 is a cross-sectional view of a SOI substrate in which a gettering layer is formed after a process shown in FIG. 1B;

FIG. 3 is a cross-sectional view of the SOI substrate forming a reinforcing rib portion;

FIGS. 4A to 4E are cross-sectional views showing a manufacturing process of a semiconductor dynamical amount sensor in a fourth embodiment mode;

FIGS. 5A to 5C are cross-sectional views showing a case in which a first concave portion is formed in a polysilicon layer by a technique except for etching;

FIGS. 6A and 6B are cross-sectional views showing a case in which the first concave portion and the reinforcing rib portion are formed in the polysilicon layer by a technique except for etching;

FIGS. 7A to 7D are cross-sectional views showing a manufacturing process of a semiconductor dynamical amount sensor in a fifth embodiment mode;

FIGS. 8A to 8D are cross-sectional views showing a manufacturing process of a semiconductor dynamical amount sensor in a sixth embodiment mode;

FIGS. 9A to 9F are cross-sectional views showing a manufacturing process of a semiconductor dynamical amount sensor in a seventh embodiment mode;

FIG. 10 is a cross-sectional view of the semiconductor dynamical amount sensor when a lower portion wiring structure explained in another embodiment mode is adopted;

FIG. 11 is a cross-sectional view of the semiconductor dynamical amount sensor when an upper portion wiring structure explained in another embodiment mode is adopted; and

FIG. 12A is a cross sectional view showing a semiconductor dynamical amount sensor taken along line XIIA-XIIA in FIG. 12B, and FIG. 12B is a plan view showing the sensor in another embodiment mode.

### DETAILED DESCRIPTION OF THE PREFERRED EMBODIMENTS

### First Embodiment Mode

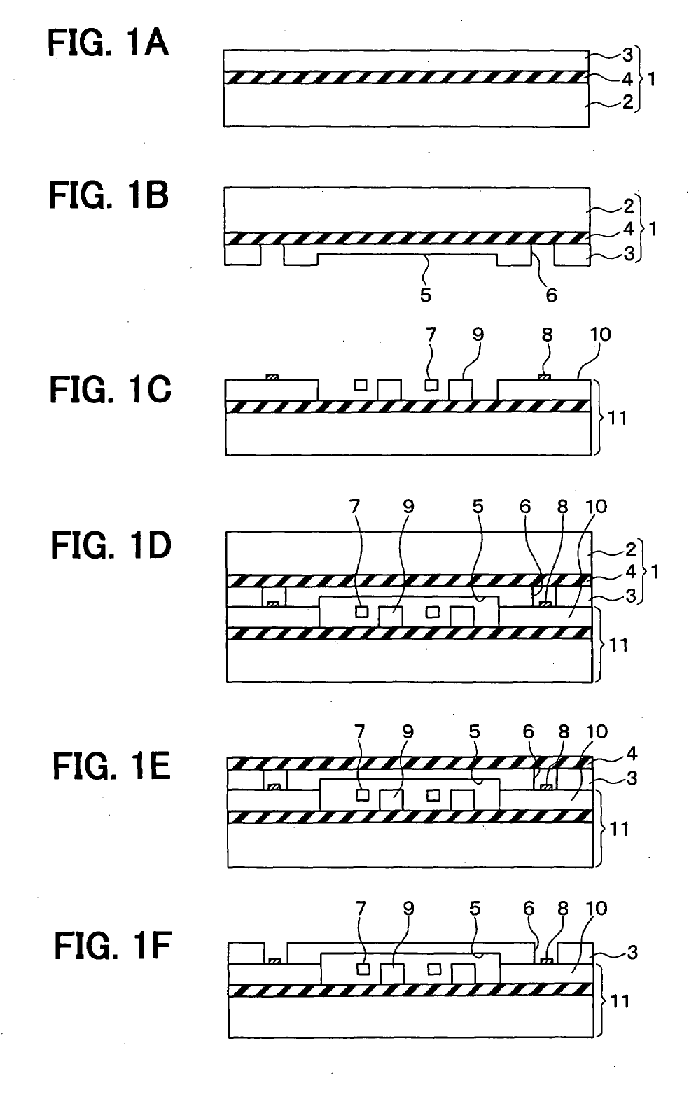

FIGS. 1A to 1F are cross-sectional views showing a manufacturing process of a semiconductor dynamical amount sensor of this embodiment mode. A manufacturing method of the semiconductor dynamical amount sensor of this embodiment mode will be explained with reference to these figures. Only one chip amount is illustrated within FIGS. 1A to 1F. However, in reality, the semiconductor dynamical amount sensor is formed in a wafer state including several hundred chips, and the semiconductor dynamical amount sensor covered with a cap is manufactured by finally dividing the chips in a chip unit.

First, a SOI substrate 1 is prepared in a process shown in FIG. 1A. The SOI substrate 1 is a substrate in which a single crystal silicon base 2 and a single crystal silicon layer 3 are joined through a burying oxide film (SiO₂) 4. The single crystal silicon base 2 in this SOI substrate 1 functions as a support base, and the single crystal silicon layer 3 functions as a cap layer, and the burying oxide film 4 functions as a joining layer. Concretely, for example, the single crystal silicon base 2 of about 300 to 800 μm in thickness is prepared. Thereafter, for example, the burying oxide film 4 of about 0.1 to 2 μm in thickness is formed by thermal oxidation, etc. on the surface of this single crystal silicon base 2. Thereafter, for example, the single crystal silicon layer 3 of about 300 to 800 μm in thickness is stuck to the surface of the burying oxide film 4 by direct joining. The single crystal silicon layer 3 is then ground and polished and is thinly formed so as to have about 5 to 500 μm in thickness (preferably, 10 to 200 μm) so that the SOI substrate 1 is formed.

Next, in a process shown in FIG. 1B, a first concave portion 5 and a second concave portion 6 are formed by a photolithography-etching process with respect to the single crystal silicon layer 3. The first concave portion 5 is formed in a place corresponding to a movable portion 7 (see FIG. 1C) of the semiconductor dynamical amount sensor to avoid contact of the movable portion 7 and the single crystal silicon layer 3. The second concave portion 6 is arranged to expose a pad portion 8 (see FIG. 1C) in the semiconductor dynamical amount sensor, and is formed so as to electrically connect the pad portion 8 and external wiring (e.g., bonding wire). Therefore, the second concave portion 6 is removed by etching until it reaches the burying oxide film 4. However, the second concave portion 6 may further pass through the burying oxide film 4 and may be also formed until the single crystal silicon base 2.

Since the depths of the first concave portion 5 and the second concave portion 6 are different, the photolithography-etching step is divisionally performed twice. For example, the first concave portion 5 is formed by performing the etching in a state in which a portion except for the first concave portion 5 among the single crystal silicon layer 3 is covered with a mask. Thereafter, a portion except for the second concave portion 6 among the single crystal silicon layer 3 is again covered with a different mask, and the etching is performed so that the second concave portion 6 can be formed.

In a subsequent process shown in FIG. 1C, for example, a sensor wafer 11 of a sensor structural body and a SOI structure is prepared as in an acceleration sensor structure having a comb teeth structure and a gyro sensor structure. The sensor structural body has the movable portion 7 having a movable electrode and a fixing portion 9 having a fixing electrode. The SOI structure has its circumferential portion 10 and the pad portion 8 formed in the circumferential portion 10, etc. The sensor structural body in the sensor wafer 11 is formed by using a conventional technique.

In a process shown in FIG. 1D, the single crystal silicon layer 3 side of the SOI substrate 1 forming the first concave portion 5 and the second concave portion 6 prepared in a process shown in FIG. 1B, and an arranging side of the sensor structural body of the sensor wafer 11 prepared in a process shown in FIG. 1C are stuck within a vacuum. For example, as a forming method of a joining portion, a flit material of so-called low melting point glass is formed in the joining portion, and a technique for performing joining at a temperature of about 200 to 450° C. within the vacuum can be then used. Further, surface processing is performed on a joining face by Ar ions, etc. by using a so-called joining technique so that the surface is activated. In this state, the joining may be also directly performed at a temperature of room temperature to about 500° C. The temperature is preferably room temperature to 450° C. This temperature is temperature at which silicon and aluminum do not excessively react when aluminum is used as a wiring layer. In this case, the joining can be performed at the room temperature. Therefore, there are effects in which the necessity of heat treatment, etc. can be removed, and the manufacturing process is simplified, and the sensor structural body, etc. are not exposed under high temperature due to the heat treatment.

Such joining is called surface activation joining. After a surface layer as obstruction of the joining is removed, binding hands of atoms of the surface are directly joined so that strong joining is performed. When the surface layer is removed, the surface after the removal attains an active state of large binding force, and the strong joining at the room temperature can be also performed. For example, the surface layer can be removed by sputter etching using an ion beam, plasma, etc. However, the surface after the sputter etching attains a state easily reacting on a circumferential gas molecule. Therefore, the sputter etching is performed within a vacuum chamber exhausted in a high vacuum, and an inert gas such as argon, etc. is preferably used in an ion beam. Such sputter etching may be performed with respect to at least one of the sensor wafer 11 and the single crystal silicon layer 3, but is preferably performed with respect to both the sensor wafer 11 and the single crystal silicon layer 3.

If such direct joining, etc. are used, it is possible to prevent a sensor characteristic change due to protrusion of an adhesive to the sensor structural body by using the adhesive. However, a joining technique using the adhesive, etc. may be also adopted in accordance with a using condition of the semiconductor dynamical amount sensor.

Subsequently, in a process shown in FIG. 1E, the single crystal silicon base 2 of the SOI substrate 1 is ground and polished until a thickness of a certain extent in a sticking state of the SOI substrate 1 and the sensor wafer 11. Thus, the single crystal silicon base 2 is formed as a thin film and is then finally removed by performing etching. The etching at this time may be dry etching using plasma, and may be also wet etching of silicon.

Thereafter, the burying oxide film 4 is removed as shown in FIG. 1F. Thus, only the single crystal silicon layer 3 is left, and a cap layer is constructed by this single crystal silicon layer 3. Further, when formation is performed by further passing through the burying oxide film 4 until the single crystal silicon base 2, no burying oxide film 4 may be removed. As mentioned above, the first concave portion 5 and the second concave portion 6 are formed in the single crystal silicon layer 3. Therefore, the sensor structural body is arranged in a forming position of the first concave portion 5, and the sensor structural body can be set so as not to come in contact with the single crystal silicon layer 3. Further, the pad portion 8 can be set to a state exposed from the single crystal silicon layer 3 through the second concave portion 6.

Subsequent processes are unillustrated in the drawings, but the SOI substrate 1 is dicing-cut together with the sensor wafer 11 as a substrate for a cap so that the SOI substrate 1 is divided in a chip unit and the semiconductor dynamical amount sensor is completed.

As explained above, in this embodiment mode, the SOI substrate 1 is used and is stuck to the sensor wafer 11 and the single crystal silicon base 2 and the burying oxide film 4 are then removed, and the single crystal silicon layer 3 is set to become the cap layer. Namely, no cap layer of a thin film is prepared from the beginning and is stuck to the sensor wafer 11. While the wafer state is held in the thick SOI substrate 1 until a sticking time, it is formed as a thin film after the sticking. Therefore, it is not necessary to set the cap layer to a thickness of a certain extent so as to prevent a crack, etc. and hold the wafer state as in a case in which the cap layer is set to a thin film from the beginning. Further, the problem that it becomes difficult to maintain the vacuum degree by flexure as in a case for constructing the cap layer by a polyimide resin film, etc. are not generated.

Accordingly, the cap layer can be thinly formed, and the semiconductor dynamical amount sensor can be thinly formed, and the vacuum degree can be easily maintained.

### Modified Example of First Embodiment Mode

As mentioned above, in this embodiment mode, the SOI substrate 1 constructed by the single crystal silicon base 2, the burying oxide film 4 and the single crystal silicon layer 3 is used in a substrate for a cap for constructing the cap layer. However, this shows one mere example, and a substrate of another structure may be also used.

For example, as the substrate for a cap, a structure formed by replacing the single crystal silicon layer 3 with a polysilicon layer may be also used, and a structure formed by replacing the single crystal silicon layer 3 with a polysilicon base may be also used. Both the single crystal silicon layer 3 and the single crystal silicon base 2 may be also changed to a polysilicon layer and a polysilicon base. Further, no materials of the support base and the cap layer are limited to silicon, but e.g., alumina, SiC, etc. may be also used, and a metal such as Kovar, etc. may be also used. These materials may be also applied to only one of the support base and the cap layer, but may be also applied to both the support base and the cap layer.

### Second Embodiment Mode

In a semiconductor dynamical amount sensor of this embodiment mode, the construction of the cap layer is changed with respect to the first embodiment mode. The others are similar to those of the first embodiment mode.

In this embodiment mode, as explained in the process shown in FIG. 1B of the first embodiment mode, a gettering layer is formed with respect to a structure in which the first concave portion 5 and the second concave portion 6 are formed in the single crystal silicon layer 3 of the SOI substrate 1. The others are similar to those of the first embodiment mode.

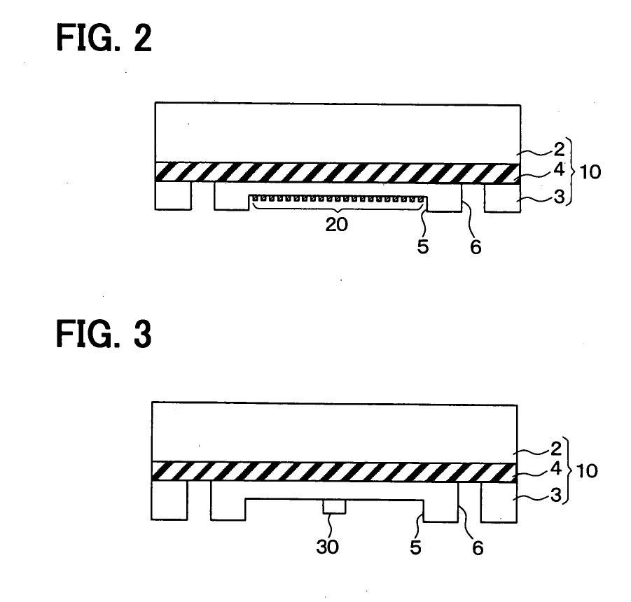

FIG. 2 is a cross-sectional view of the SOI substrate 1 in which the gettering layer 20 is formed after the process shown in the above FIG. 1B. As shown in this figure, the gettering layer 20 is formed on a bottom face of the first concave portion 5 in the single crystal silicon layer 3. This gettering layer 20 is arranged to more reliably maintain a high vacuum state when a spatial portion formed between the single crystal silicon layer 3 as a cap layer and the sensor wafer 11 is set to a vacuum. The gettering layer 20 is constructed by a transition metal such as Zr, Ti, Nb, Ta, V, etc., or their alloy or compound, an alloy or a compound of Cr, Mn, Fe, Co, Ni, Al, Y, La and at least one element selected from rare earth, e.g., a binary alloy, Ti—V, Zr—Al, Zr—V, Zr—Fe and Zr—Ni, a ternary alloy, Zr—V—Fe and Zr—Co-rare earth, or a multi-component system alloy zirconium alloy, etc. For example, the gettering layer 20 is formed as follows. A first layer of a non-evaporation type getter material having an area sufficiently wider than that of the bottom face of the first concave portion 5 is deposited on this bottom face by cathode deposition. Thereafter, at least a second layer of a non-evaporation type getter alloy having a low activation temperature is deposited on this first layer by the cathode deposition. For example, a manufacturing method of this gettering layer 20 is known in JP-A-2005-916, etc., and its explanation is therefore omitted.

Thus, it is possible to more reliably maintain the vacuum degree of the spatial portion formed between the single crystal silicon layer 3 as a cap layer and the sensor wafer 11 by forming the gettering layer 20.

### Third Embodiment Mode

In a semiconductor dynamical amount sensor of this embodiment mode, the construction of the cap layer is also changed with respect to the first embodiment mode. The others are similar to those of the first embodiment mode.

In this embodiment mode, as explained in the process shown in FIG. 1B of the first embodiment mode, a reinforcing rib portion is formed with respect to a structure in which the first concave portion 5 and the second concave portion 6 are formed in the single crystal silicon layer 3 of the SOI substrate 1. The others are similar to those of the first embodiment mode.

FIG. 3 is a cross-sectional view of the SOI substrate 1 forming the reinforcing rib portion therein. The reinforcing rib portion 30 reinforces the single crystal silicon layer 3 thinly formed by forming the first concave portion 5, and is partially arranged within the first concave portion 5. In this embodiment mode, the reinforcing rib portion 30 is constructed in a square shape in a central position of the first concave portion 5, but may be also constructed in a rectangular shape. Further, for example, when the first concave portion 5 is constructed in the square shape, the reinforcing rib portion 30 may be also constructed in a straight line shape for connecting one side among two opposed sides and a cross shape for connecting both the sides. Further, the reinforcing rib portion 30 may be also set to a construction in which the two opposed sides are connected by the reinforcing rib portion 30 of plural straight line shapes. A tip position of such a reinforcing rib portion 30 is recessed from a joining face to the sensor wafer 11 among the single crystal silicon layer 3, and the reinforcing rib portion 30 is set so as not to come in contact with the sensor structural body.

In the above process of FIG. 1B, the structure having the first concave portion 5 and the second concave portion 6 is realized by performing the etching of two stages. However, if the etching of three stages is performed, the reinforcing rib portion 30 can be formed. For example, the first concave portion 5 is first formed until a depth attaining the tip position of the reinforcing rib portion 30. Thereafter, the etching is performed while a forming portion of the reinforcing rib portion 30 and the circumference of the first concave portion 5 are covered with a mask. Thus, a structure having the reinforcing rib portion 30 on the bottom face of the first concave portion 5 is formed. Subsequently, a portion except for a formation schedule position of the second concave portion 6 among the single crystal silicon layer 3 is covered with a mask, and the etching is performed. Thus, the second concave portion 6 is formed, and the first concave portion 5 and the second concave portion 6 having the reinforcing rib portion 30 in the single crystal silicon layer 3 are formed.

### Fourth Embodiment Mode

In this embodiment mode, the cap layer in the semiconductor dynamical amount sensor is manufactured by a transfer technique with respect to the first embodiment mode. The others are similar to those of the first embodiment mode, and only different portions will be explained.

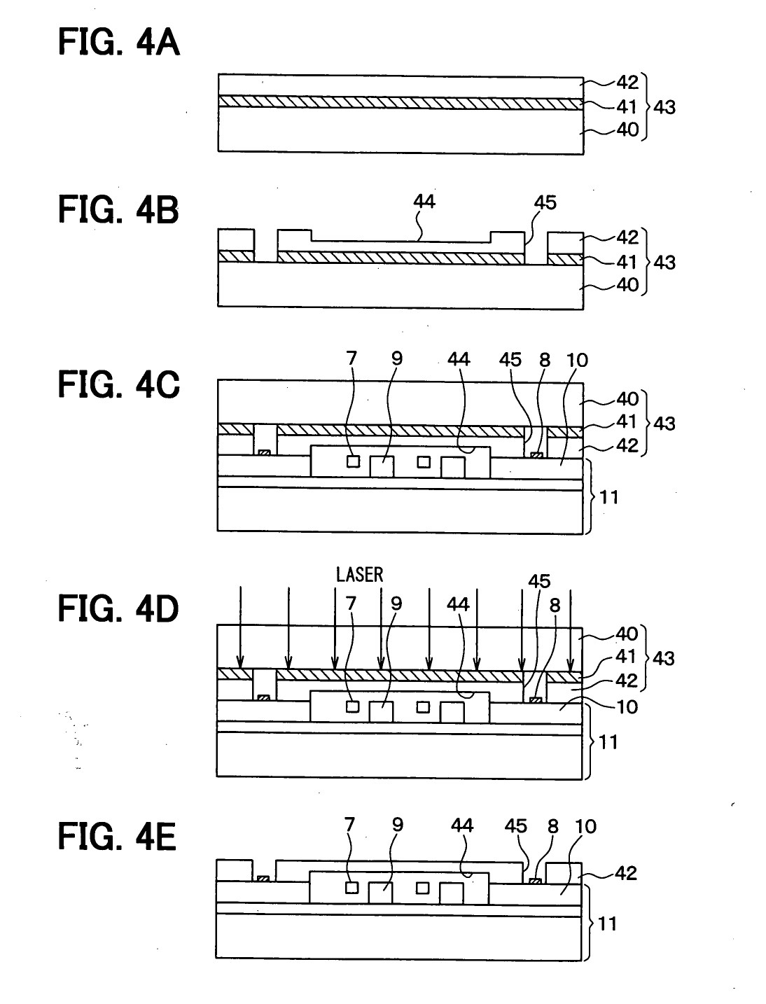

FIGS. 4A to 4E are cross-sectional views showing a manufacturing process of the semiconductor dynamical amount sensor of this embodiment mode. A manufacturing method of the semiconductor dynamical amount sensor of this embodiment mode will be explained with reference to these figures.

First, in a process shown in FIG. 4A, a substrate 43 of a wafer state sequentially forming an amorphous silicon layer 41 and a polysilicon layer 42 on the surface of a quartz glass base 40 is prepared as a substrate for a cap. The quartz glass base 40 is prepared as a translucent support base constructed by a material for transmitting a laser beam. This translucent support base may be also constructed by a material except for quartz glass, e.g., heat resisting glass. The amorphous silicon layer 41 is prepared as a light absorbing layer constructed by a material for absorbing the laser beam. For example, a silicon nitride layer, etc. are enumerated in addition to amorphous silicon as such a material. The polysilicon layer 42 is arranged to be set to the cap layer, and the above various materials can be used as the cap layer.

Subsequently, in processes shown in FIGS. 4B and 4C, similar to FIGS. 1B and 1C, a first concave portion 44 and a second concave portion 45 are formed in the polysilicon layer 42. Thereafter, the polysilicon layer 42 of the substrate for a cap is stuck to the sensor wafer 11.

Thereafter, for example, the laser beam (excimer laser, etc.) of 100 to 350 nm in wavelength is irradiated from the quartz glass base 40 side as energy for separation. Thus, since the laser beam is transmitted through the quartz glass base, the laser beam is irradiated to the amorphous silicon layer 41. Therefore, the laser beam is absorbed to the amorphous silicon layer 41 and binding force of the amorphous silicon layer 41 is broken by its energy. The quartz glass is separated from the polysilicon layer 42 with the amorphous silicon layer 41 as a separating layer. Thus, the polysilicon layer 42 set to the cap layer is left, and the remaining portion of the amorphous silicon layer 41 and one portion of the polysilicon layer 42 are removed in accordance with necessity. Thus, the cap layer constructed by the polysilicon layer 42 set to a predetermined desirable film thickness can be formed.

The cap layer can be also thinly formed by the manufacturing method of the semiconductor dynamical amount sensor of this embodiment mode explained above, and effects similar to those of the above first embodiment mode can be obtained. Further, when such a transfer technique is used, the translucent support base can be reutilized. Therefore, manufacture cost can be also reduced.

Here, the laser beam is used to realize the transfer technique, but it is sufficient to separate the translucent support base from the cap layer in a separating layer as irradiated light. For example, an X-ray, an ultraviolet ray, visible light, an infrared ray (heat ray), a laser beam, a millimeter wave, a micro wave, an electron ray, a radiant ray (α ray, β ray, γ ray), etc. are enumerated. For example, such a transfer technique is known in JP-A-10-125931. Therefore, its detailed explanation is omitted, but all materials publicly known can be also used in the above translucent support substrate and light absorbing layer.

### Modified Example of Fourth Embodiment Mode

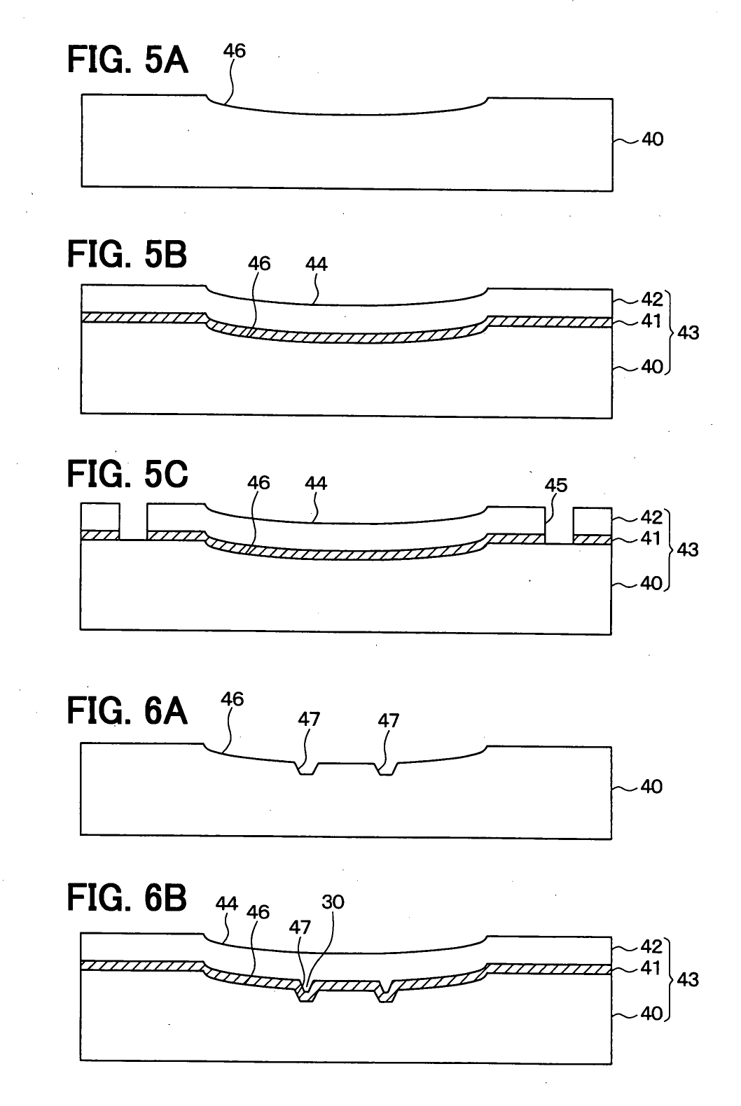

As mentioned above, in the fourth embodiment mode, the first concave portion 44 is formed in the polysilicon layer 42 by etching, but another technique can be also used. FIGS. 5A to 5C are cross-sectional views showing a case in which the first concave portion 44 is formed by a technique except for etching in the polysilicon layer 42.

First, as shown in FIG. 5A, for example, a concave portion 46 of a curved surface shape (dome shape) in section is formed in a place corresponding to the first concave portion 44 among the quartz glass base 40 set to a translucent support base in advance. As shown in FIG. 5B, the amorphous silicon layer 41 and the polysilicon layer 42 are laminated and formed on this concave portion 46. At this time, since the concave portion 46 is previously formed in the quartz glass base 40, its shape is also inherited in the amorphous silicon layer 41 and the polysilicon layer 42. As shown in FIG. 5C, the second concave portion 45 is then formed in the polysilicon layer 42. Thereafter, the semiconductor dynamical amount sensor can be manufactured by performing processes on and after FIG. 4C. In accordance with such a construction, a forming process of the first concave portion 44 can be omitted. Therefore, a manufacturing process can be further simplified and manufacture cost can be reduced.

Further, in this case, the reinforcing rib portion 30 can be also simultaneously formed. FIGS. 6A and 6B are cross-sectional views showing a situation in which the reinforcing rib portion 30 is also simultaneously formed in a case for forming the first concave portion 44 in the polysilicon layer 42 by a technique except for etching.

First, as shown in FIG. 6A, a groove portion 47 for the reinforcing rib portion formed by setting the concave portion 46 formed in the quartz glass base 40 so as to be further partially recessed is formed. The shape of the groove portion 47 for the reinforcing rib portion is arbitrary, but its side wall is preferably formed in a taper shape. If the process shown in the above FIG. 5B is performed in a process shown in FIG. 6B with respect to such a quartz glass base 40, the shape of the groove portion 47 for the reinforcing rib portion is also inherited in the amorphous silicon layer 41 and the polysilicon layer 42. It is possible to form the reinforcing rib portion 30 directed outward with respect to the polysilicon layer 42. At this time, if the polysilicon layer 42 is thickly set to a certain extent, the surface of the polysilicon layer 42 becomes flat. Thereafter, the semiconductor dynamical amount sensor can be manufactured by performing the process shown in the above FIG. 5C and the processes on and after FIG. 4C although these processes are not illustrated in the drawings. Thus, the reinforcing rib portion 30 can be also simultaneously formed at a film forming time of the polysilicon layer 42.

Here, the case for forming the concave portion 46 of a curved surface shape in section in the translucent support base has been explained. However, the concave portion of a rectangular shape, a pyramidal shape and a diaphragm shape in section may be also formed.

### Fifth Embodiment Mode

In this embodiment mode, a separating technique of the single crystal silicon base 2 in the semiconductor dynamical amount sensor, etc. are changed with respect to the first embodiment mode. The others are similar to those of the first embodiment mode.

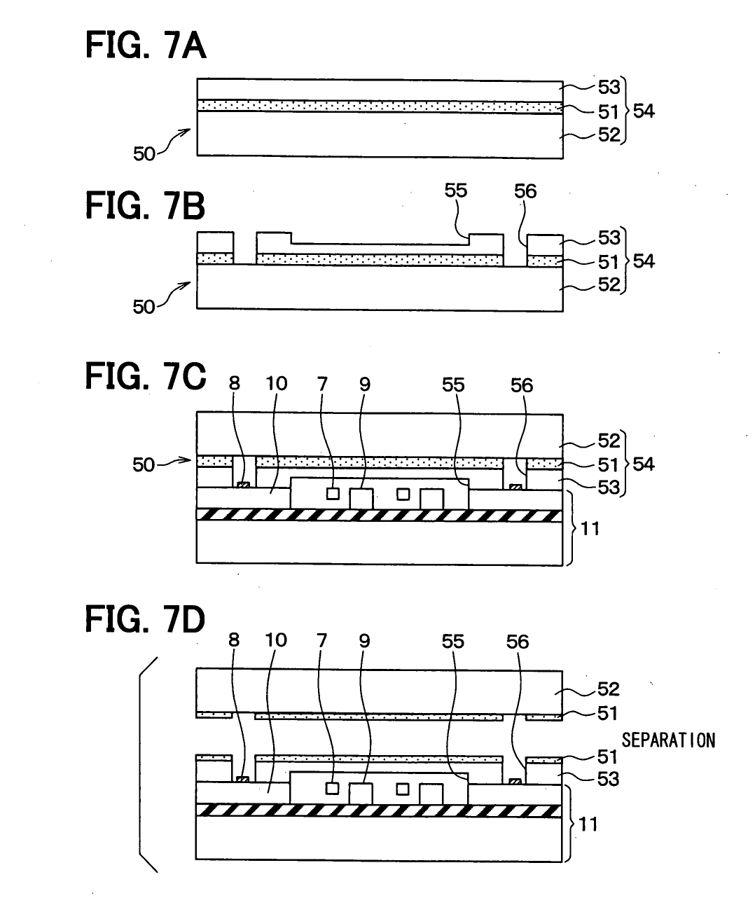

FIGS. 7A to 7D are cross-sectional views showing a manufacturing process of the semiconductor dynamical amount sensor of this embodiment mode. In a process shown in FIG. 7A, a substrate 54 for a cap is prepared by forming a hydrogen ion implanting layer 51 in the position of a predetermined depth of a single crystal silicon substrate 50. In this substrate 54 for a cap, the hydrogen ion implanting layer 51 is set to a boundary, and the layer of a thick side in thickness is set to a support base 52, and the layer of a thin side in thickness is set to a cap layer 53. In a process shown in FIG. 7B, a first concave portion 55 and a second concave portion 56 are formed with respect to this substrate 54 for a cap. At this time, the second concave portion 56 is set so as to pass through the hydrogen ion implanting layer 51 and reach until the support base 52.

Subsequently, in a process shown in FIG. 7C, similar to FIG. 1C, the sensor wafer 11 of the sensor structural body and the SOI structure is prepared. The sensor structural body has the movable portion 7 and the fixing portion 9. The SOI structure has its circumferential portion 10 and the pad portion 8 formed in the circumferential portion 10, etc. A structure similar to that of FIG. 1D is then set by sticking the substrate 54 for a cap and the sensor wafer 11. Thereafter, in a process shown in FIG. 7D, the support base 52 is separated from the cap layer 53 by a smart cut method with the hydrogen ion implanting layer 51 as a separating layer. Concretely, for example, the hydrogen ion implanting layer 51 is divisionally cut and the support base 52 can be separated from the cap layer 53 by taking heat treatment of about 400 to 600° C. as energy for separation.

Thus, a structure similar to that of the above first embodiment mode can be also realized when the support base 52 is separated from the cap layer 53 by the smart cut method. The smart cut method is known in JP-A-2000-19197, etc., and its detailed explanation is therefore omitted.

### Sixth Embodiment Mode

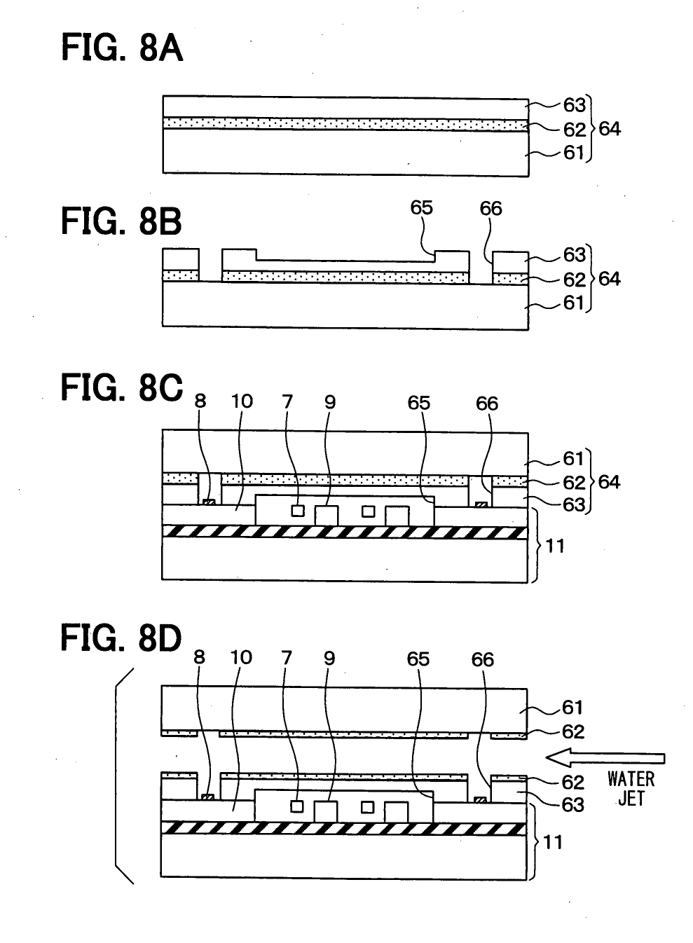

In the above fifth embodiment mode, the case using the smart cut method has been explained. However, in this embodiment mode, a case for manufacturing the semiconductor dynamical amount sensor by using an ELTRAN method will be explained. FIGS. 8A to 8D are cross-sectional views showing a manufacturing process of the semiconductor dynamical amount sensor when the ELTRAN method is used.

In a process shown in FIG. 8A, for example, a porous silicon layer 62 forming a hole of about 600 Å in average diameter is formed on the surface of a single crystal silicon substrate 61. Thereafter, a single crystal epitaxial silicon layer 63 is formed on the porous silicon layer 62 by epitaxial growth able to perform low temperature growth of molecular beam epitaxial growth, plasma CVD, a pressure reduction CVD method, optical CVD, a bias-sputter method, a liquid phase growing method, etc. Thus, a substrate 64 for a cap in which the single crystal silicon substrate 61 is set to a support base and the single crystal epitaxial silicon layer 63 is set to a cap layer, is formed.

Thereafter, in processes shown in FIGS. 8B and 8C, processes similar to those of FIGS. 7B and 7C are performed, and a first concave portion 65 and a second concave portion 66 are formed, and the substrate 64 for a cap and the sensor wafer 11 are then stuck. In a process shown in FIG. 8D, the single crystal silicon substrate 61 is separated from the single crystal epitaxial silicon layer 63 by the ELTLAN method with the porous silicon layer 62 as a separating layer. Concretely, for example, the porous silicon layer 62 is divisionally cut by giving force using a liquid jet or a gas jet as energy for separation. Thus, the single crystal silicon substrate 61 can be separated from the single crystal epitaxial silicon layer 63.

Thus, a structure similar to that of the above fifth embodiment mode can be also realized when the single crystal silicon substrate 61 is separated from the single crystal epitaxial silicon layer 63 by the ELTLAN method. The ELTLAN method (particularly, a forming technique of the porous silicon layer 62 and a divisional cutting method of the porous silicon layer 62) is known in JP-A-5-21338, JP-A-11-5064, etc., and its detailed explanation is therefore omitted.

### Seventh Embodiment Mode

In this embodiment mode, a connecting structure with the exterior of the pad portion 8 in the semiconductor dynamical amount sensor shown in the sixth embodiment mode is changed. The others are similar to those of the sixth embodiment mode.

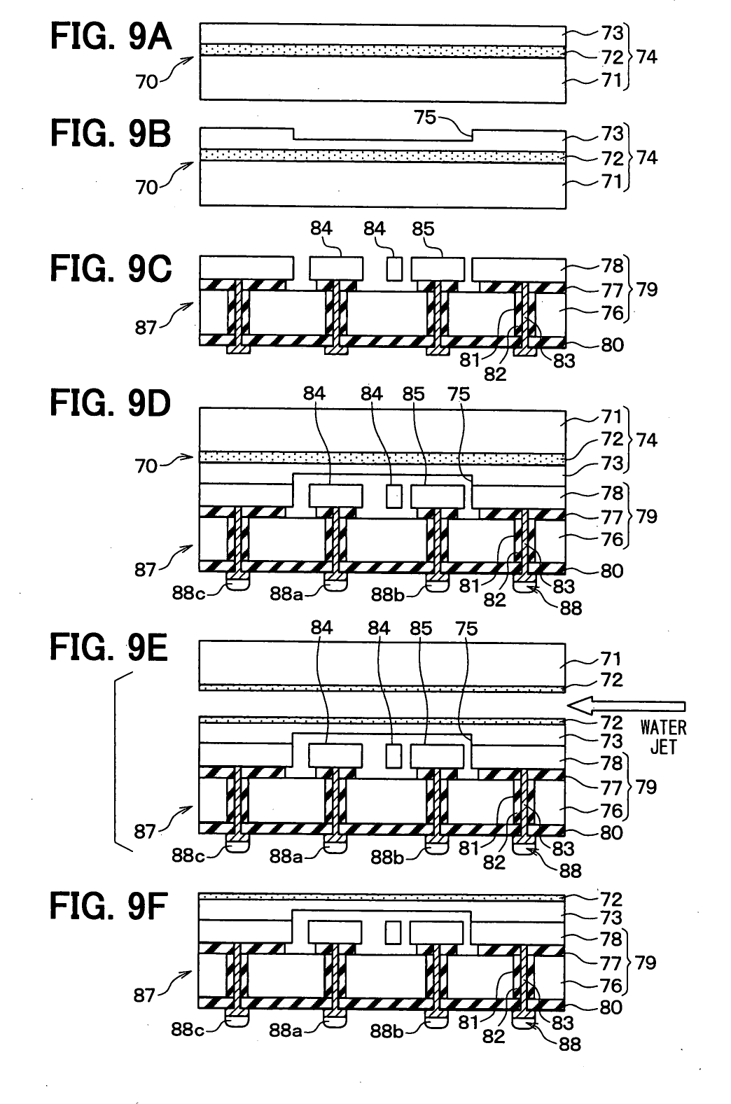

FIGS. 9A to 9F are cross-sectional views showing a manufacturing process of the semiconductor dynamical amount sensor of this embodiment mode. First, in a process shown in FIG. 9A, a porous silicon layer 72 is formed on the surface of a single crystal silicon substrate 71 of p-type by a technique similar to that of FIG. 8A. Further, a substrate 74 for a cap forming a single crystal epitaxial silicon layer 73 on the surface of the porous silicon layer 72 is formed.

Subsequently, in a process shown in FIG. 9B, in a place corresponding to a sensor structural body of the semiconductor dynamical amount sensor described later, a first concave portion 75 for avoiding contact of the sensor structural body and the single crystal epitaxial silicon layer 73 is formed by a photolithography-etching process with respect to the single crystal epitaxial silicon layer 73. At this time, no second concave portion 56 (see FIG. 7C) corresponding to the pad portion 8 shown in the sixth embodiment mode is formed.

On the other hand, in a process shown in FIG. 9C, a SOI substrate 79 forming a single crystal silicon layer 78 through a burying oxide film 77 on a single crystal silicon base 76 is prepared. After an oxide film 80 is formed on a rear face of the single crystal silicon base 76, a via hole 81 passing through the burying oxide film 77 from the rear face of the single crystal silicon base 76 and reaching the single crystal silicon layer 78 is formed in a predetermined desirable position of the single crystal silicon base 76 by photolithography-etching. Further, an oxide film 82 is arranged in an inner wall of the via hole 81 by thermal oxidation, etc. Thereafter, a metallic film is arranged so as to bury the interior of the via hole 81, and is then patterned so that a through electrode 83 is formed. Thereafter, the single crystal silicon layer 78 is patterned by a process similar to that of FIG. 1C. Further, a predetermined desirable portion of the burying oxide film 77 is removed from an opening portion of the single crystal silicon layer 78. Thus, a sensor wafer 87 of the sensor structural body having a movable portion 84 having a movable electrode and a fixing portion 85 having a fixing electrode, and the SOI structure having its circumferential portion 86, etc. is formed.

In a process shown in FIG. 9D, a bump 88 for mounting a flip chip is arranged on the surface of the through electrode 83. This bump 88 becomes a flip chip electrode and electric connection with the exterior is made. Concretely, a bump 88a becomes an external taking-out terminal of the movable portion 84, and a bump 88b becomes an external taking-out terminal of the fixing portion 85, and a bump 88c becomes an external taking-out terminal of the circumferential portion 86. Thereafter, an arranging side of the first concave portion 75 of the substrate 74 for a cap and an arranging side of the sensor structural body of the sensor wafer 87 are stuck by a technique similar to that of FIG. 1D.

Thereafter, in a process of FIG. 9E, similar to FIG. 8D, the single crystal silicon substrate 71 is separated from the single crystal epitaxial silicon layer 73 by the ELTLAN method with the porous silicon layer 72 as a separating layer. Concretely, for example, the single crystal silicon substrate 71 can be separated from the single crystal epitaxial silicon layer 73 by divisionally cutting the porous silicon layer 72 by a liquid jet or a gas jet. Thus, as shown in FIG. 9F, it is possible to obtain the semiconductor dynamical amount sensor of a structure in which the external taking-out terminal is formed on a rear face as a face opposed to a formed side of the sensor structural body among the sensor wafer 87. The semiconductor dynamical amount sensor of such a structure may be also set.

In this embodiment mode, the single crystal epitaxial silicon layer 73 is enumerated as an example and has been explained as the cap layer. However, instead of this, polysilicon and amorphous silicon may be also used. Further, an insulating film such as an SiO₂ film, an Si₃N₄ film, etc. a metallic film, etc. can be also formed on the porous silicon layer 72 as a separating layer.

### Other Embodiment Modes

In each of the above embodiment modes, a case for directly joining the substrate for a cap to the sensor wafer 11 has been explained, but these members may not be necessarily directly joined. For example, the substrate for a cap and the sensor wafer 11 may be also joined through a spacer constructed by a silicon oxide film, a silicon nitride film, etc. In this case, since a clearance is formed by the spacer between the substrate for a cap and the sensor wafer 11, contact of the cap layer and the sensor structural body can be prevented even when the first concave portions 5, 44 are not arranged.

Similarly, in each of the above embodiment modes, the first concave portions 5, 44 are formed in the cap layer to avoid the contact of the cap layer and the sensor structural body. However, if the sensor structural body is set to a construction recessed from its circumferential portion 10, the contact of the cap layer and the sensor structural body can be avoided even when the first concave portions 5, 44 are not arranged in the cap layer.

Further, in the above first to third embodiment modes, the first concave portion 5 is set to a rectangular shape in section, but may be also set to a curved surface shape, a pyramidal shape, a trapezoidal shape, etc. in section as shown in the modified example of the fourth embodiment mode. When the first concave portion 5 is particularly set to a curved surface shape in section, it is preferable since the first concave portion 5 is strengthened in stress.

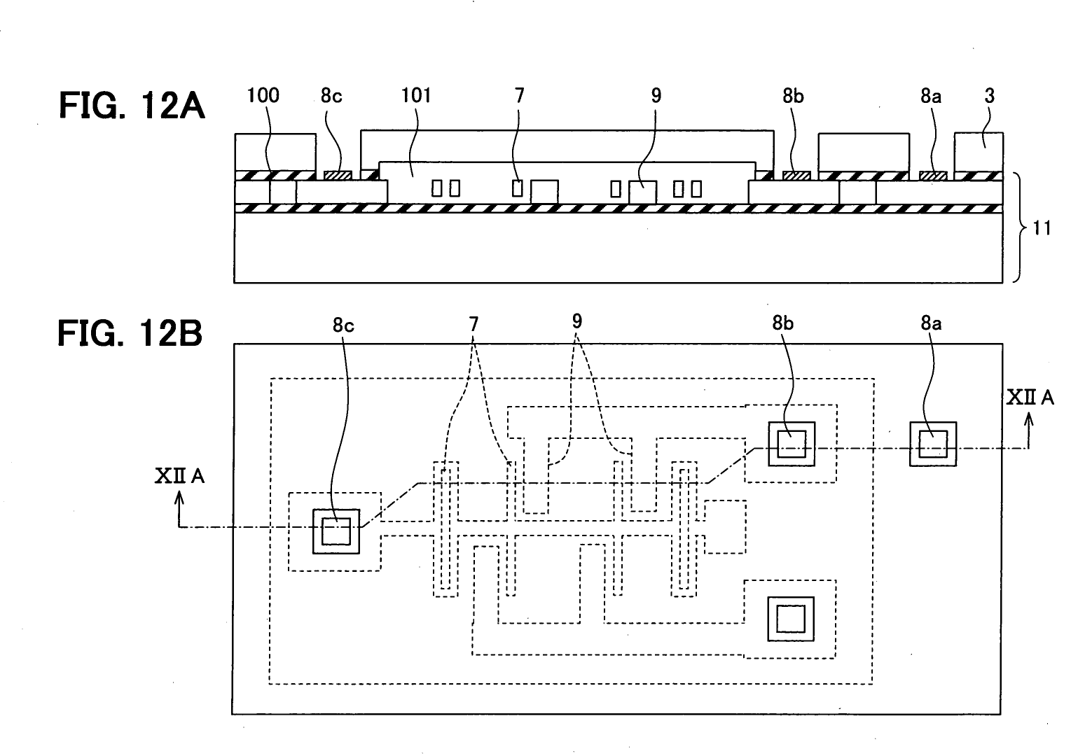

Further, in the above first to third embodiment modes, a semiconductor dynamical amount sensor may have a construction shown in FIGS. 12A and 12B. Specifically, the pad portion 8 may includes a periphery electrode pad 8a disposed on a periphery of the substrate 11, a fixed electrode pad 8b for retrieving from the fixing portion 9, and a movable electrode pad 8c for retrieving from the movable portion 7. Further, an insulation film such as a SiO₂ film is disposed between the wafer 11 and the single crystal silicon layer 3. In FIG. 12A, 101 represents a fixed part for the movable portion 7.

Further, in the above first to sixth embodiment modes, no electric connection relation of the pad portion 8 as an external taking-out terminal, the movable portion 7, the fixing portion 9 and the circumferential portion 10 has been particularly explained. However, the electric connection of the movable portion 7, the fixing portion 9 and the circumferential portion 10 may be also realized by a lower portion wiring structure, and may be also realized by an upper portion wiring (wiring in the air) structure. In this case, it is necessary to form an unillustrated oxide film, etc. as an insulator in a joining portion such that the cap layer and the sensor structural body are not electrically short-circuited.

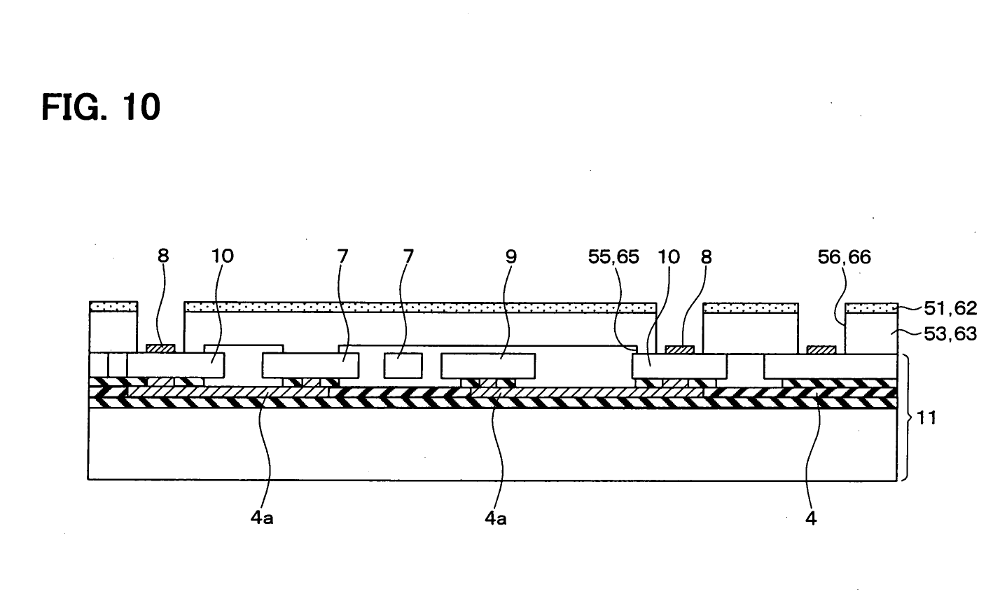

FIG. 10 is a cross-sectional view of the semiconductor dynamical amount sensor when the lower portion wiring structure is adopted. This figure corresponds to a case in which the semiconductor dynamical amount sensor is manufactured by the manufacturing method explained in the above fifth and sixth embodiment modes. As shown in this figure, the burying oxide film 4 is set to a multilayer structure, and, e.g., a lower portion wiring 4a constructed by polysilicon doping impurities thereto is formed within the burying oxide film 4. The movable portion 7 and the fixing portion 9 and the circumferential portion 10 doping impurities through this lower portion wiring 4a are electrically connected. Thus, it is possible to make electric connection with the exterior through the pad portion 8 formed on the surface of the circumferential portion 10.

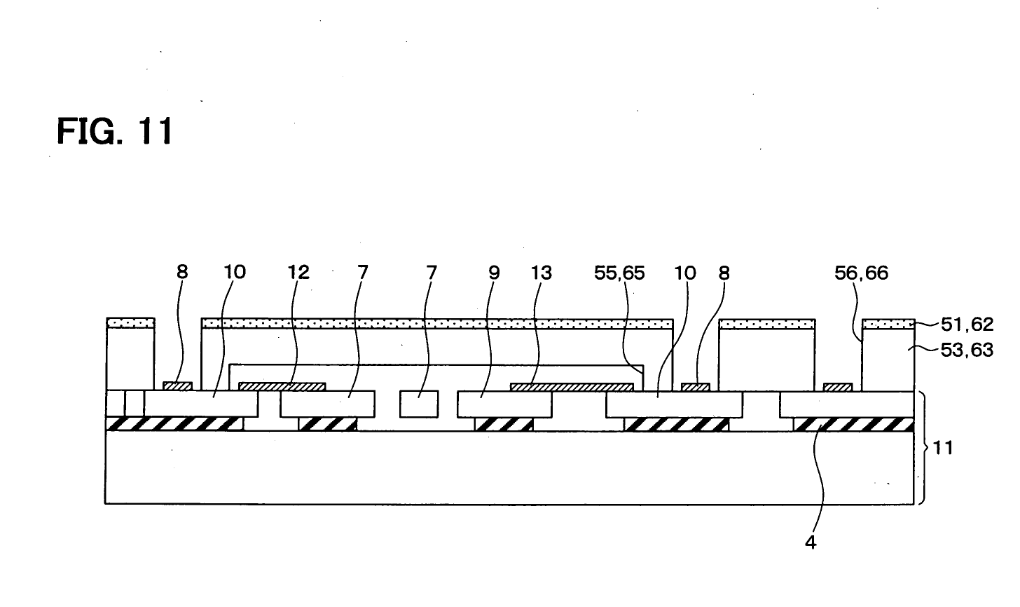

FIG. 11 is a cross-sectional view of the semiconductor dynamical amount sensor when the upper portion wiring structure is adopted. This figure also corresponds to a case in which the semiconductor dynamical amount sensor is manufactured by the manufacturing method explained in the above fifth and sixth embodiment modes. As shown in this figure, an upper portion wiring 12 for connecting desired portions on the surface of a support portion for supporting a movable electrode among the movable portion 7 and the surface of the circumferential portion 10 is formed and an upper portion wiring 13 for connecting desired portions on the surface of the fixing portion 9 and the surface of the circumferential portion 10. Since impurities are doped to the movable portion 7, the fixing portion 9 and the circumferential portion 10 in advance, it is possible to make electric connection with the exterior through the pad portion 8 formed on the surface of the circumferential portion 10. For example, such upper portion wirings 12, 13 are constructed by an aluminum wiring layer, and are formed simultaneously with the pad portion 8, and are patterned before the movable portion 7, the fixing portion 9 and the circumferential portion 10 are patterned. Namely, after the upper portion wirings 12, 13 are patterned, the movable portion 7, the fixing portion 9 and the circumferential portion 10 are patterned by performing etching through an unforming area of the upper portion wirings 12, 13. Thus, the structure shown in FIG. 11 can be realized.

In FIG. 11, for example, the case for constructing the upper portion wirings 12, 13 by an aluminum wiring layer has been explained. However, the upper portion wirings 12, 13 can be also formed by a member different from the pad portion 8, e.g., polysilicon doping impurities such as arsenic, phosphorus, etc. thereto. Further, the upper portion wirings 12, 13 can be also formed by tungsten, copper, titanium or these alloy, a laminating body as a metal except for aluminum.

Further, FIGS. 10 and 11 show examples attaining a state in which the hydrogen ion implanting layer 51 or the porous silicon layer 62 is left on the surfaces of the cap layer 53 and the single crystal epitaxial silicon layer 63. However, in accordance with necessity, these layers may be also removed by etching or polishing, etc.

In each of the above embodiment modes, the spatial portion is formed by forming the concave portion in a position corresponding to the sensor structural body with respect to the cap layer. However, if it is a structure for forming the spatial portion between the cap layer and the sensor structural body, another structure may be also used. For example, even when the cap layer itself is set to be flat, the spatial portion may be also formed by arranging a clearance between the cap layer and the sensor structural body.

The above disclosure has the following aspects.

According to a first aspect of the present disclosure, a physical quantity sensor includes: a semiconductor substrate; a sensor element disposed in the substrate; and a cap layer disposed on the substrate so that a space between the cap layer and the substrate is provided. The cap layer is directly bonded to the substrate, and the cap layer faces the sensor element in such a manner that the sensor element is disposed in the space. Further, the vacuum in the space is maintained, and the thickness of the sensor is reduced.

The above sensor has no adhesive between the first and second wafers. Thus, penetration of the adhesive to the sensor element is not occurred in the above sensor.

Alternatively, the substrate may be provided from a first wafer. The cap layer may be provided from a second wafer, which is bonded to the first wafer and partially separated from the first wafer to remain the cap layer on the first wafer. The first wafer together with the cap layer is divided into a plurality of chips.

Alternatively, the substrate may be provided from a first wafer, and the cap layer may be provided from a second wafer, which is bonded to the first wafer and partially thinned so as to remain the cap layer on the first wafer.

Alternatively, the sensor may further include a gettering layer for maintaining vacuum in the space. The gettering layer is disposed on the cap layer and in the space. This gettering layer maintains vacuum in the space.

Alternatively, the sensor may further include a reinforce rib for reinforcing the cap layer. The reinforce rib is disposed on the cap layer and in the space. The vacuum in the space is surely maintained without cracking the cap layer.

According to a second aspect of the present disclosure, a method for manufacturing a physical quantity sensor includes: forming a sensor element in a first wafer; stacking a support substrate, a connection layer and a cap layer in this order so that a second wafer is prepared; bonding the cap layer of the second wafer to the first wafer in such a manner that the sensor element is disposed in a space between the first wafer and the second wafer; removing the support substrate and the connection layer from the second wafer; and dividing the first wafer together with the cap layer into a plurality of chips so that a plurality of physical quantity sensors is formed.

The above method provides to maintain vacuum in the space and to reduce thickness of the sensor.

Alternatively, the method may further include forming the space in the cap layer before the bonding the cap layer. The space in the cap corresponds to the sensor element in the first wafer. Further, the connection layer may provide a peel-off layer, and the removing the support substrate and the connection layer includes energizing the peel-off layer so that the peel-off layer is peeled off from the cap layer. Furthermore, the support substrate may be made of transparent material, and the peel-off layer may be made of photo absorption material. The energizing the peel-off layer is performed by irradiating light on the peel-off layer through the support substrate.

Alternatively, the peel-off layer may be made of a hydrogen ion implantation layer, and the energizing the peel-off layer is performed by heating the peel-off layer.

Alternatively, the peel-off layer may be made of porous silicon, and the energizing the peel-off layer is performed by jetting liquid or gas toward the peel-off layer.

Alternatively, the method may further include: sputtering and etching a surface of at least one of the cap layer and the first wafer to clean the surface before the bonding the cap layer to the first wafer. The bonding the cap layer to the first wafer is performed in such a manner that a coupling end of an atom on the cleaned surface of the one of the cap layer and the first wafer is directly bonded to another coupling end of an atom on a surface of the other one of the cap layer and the first wafer.

Alternatively, the first wafer may be a SOI wafer, and the second wafer is another SOI wafer, the cap layer may be made of silicon, and the bonding the cap layer to the first wafer is performed in vacuum so that the space between the cap layer and the first wafer is evacuated. Further, the method may further include: activating a surface of one of the cap layer and the first wafer by using a predetermined ions before the bonding the cap layer to the first wafer. The bonding the cap layer to the first wafer is performed under a predetermined temperature in a range between room temperature and 450° C. Furthermore, the removing the support substrate and the connection layer may include: grinding a part of the support substrate; etching a remaining part of the support substrate; and removing the connection layer.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A physical quantity sensor comprising:
a semiconductor substrate;
a sensor element disposed in the substrate; and
a cap layer disposed on the substrate so that a space between the cap layer and the substrate is provided, wherein
the cap layer is directly bonded to the substrate, and
the cap layer faces the sensor element in such a manner that the sensor element is disposed in the space.

2. The sensor according to claim 1, wherein
the substrate is provided from a first wafer,
the cap layer is provided from a second wafer, which is bonded to the first wafer and partially separated from the first wafer to remain the cap layer on the first wafer, and
the first wafer together with the cap layer is divided into a plurality of chips.

3. The sensor according to claim 1, wherein
the substrate is provided from a first wafer,
the cap layer is provided from a second wafer, which is bonded to the first wafer and partially thinned so as to remain the cap layer on the first wafer, and
the first wafer together with the cap layer is divided into a plurality of chips.

4. The sensor according to claim 1, further comprising:
a gettering layer for maintaining vacuum in the space, wherein
the gettering layer is disposed on the cap layer and in the space.

5. The sensor according to claim 1, further comprising:
a reinforce rib for reinforcing the cap layer, wherein
the reinforce rib is disposed on the cap layer and in the space.

6. A method for manufacturing a physical quantity sensor, the method comprising:
forming a sensor element in a first wafer;
stacking a support substrate, a connection layer and a cap layer in this order so that a second wafer is prepared;
bonding the cap layer of the second wafer to the first wafer in such a manner that the sensor element is disposed in a space between the first wafer and the second wafer;
removing the support substrate and the connection layer from the second wafer; and
dividing the first wafer together with the cap layer into a plurality of chips so that a plurality of physical quantity sensors is formed.

7. The method according to claim 6, further comprising:
forming the space in the cap layer before the bonding the cap layer, wherein
the space in the cap layer corresponds to the sensor element in the first wafer.

8. The method according to claim 7, wherein
the connection layer provides a peel-off layer, and
the removing the support substrate and the connection layer includes energizing the peel-off layer so that the peel-off layer is peeled off from the cap layer.

9. The method according to claim 8, wherein
the support substrate is made of transparent material,
the peel-off layer is made of photo absorption material, and
the energizing the peel-off layer is performed by irradiating light on the peel-off layer through the support substrate.

10. The method according to claim 8, wherein
the peel-off layer is made of a hydrogen ion implantation layer, and
the energizing the peel-off layer is performed by heating the peel-off layer.

11. The method according to claim 8, wherein
the peel-off layer is made of porous silicon, and
the energizing the peel-off layer is performed by jetting liquid or gas toward the peel-off layer.

12. The method according to claim 7, further comprising:
forming a gettering layer on the cap layer in the space, wherein
the gettering layer is capable of maintaining vacuum in the space.

13. The method according to claim 7, further comprising:
forming a reinforce rib on the cap layer in the space, wherein
the reinforce rib is capable of reinforcing the cap layer.

14. The method according to claim 6, further comprising:
sputtering and etching a surface of at least one of the cap layer and the first wafer to clean the surface before the bonding the cap layer to the first wafer, wherein
the bonding the cap layer to the first wafer is performed in such a manner that a coupling end of an atom on the cleaned surface of the one of the cap layer and the first wafer is directly bonded to another coupling end of an atom on a surface of the other one of the cap layer and the first wafer.

15. The method according to claim 8, wherein
the bonding the cap layer to the first wafer is performed at a room temperature.

16. The method according to claim 8, wherein
the first wafer is a SOI wafer, and the second wafer is another SOI wafer,
the cap layer is made of silicon, and
the bonding the cap layer to the first wafer is performed in vacuum so that the space between the cap layer and the first wafer is evacuated.

17. The method according to claim 16, further comprising:
activating a surface of one of the cap layer and the first wafer by using a predetermined ions before the bonding the cap layer to the first wafer, wherein
the bonding the cap layer to the first wafer is performed under a predetermined temperature in a range between room temperature and 450° C.

18. The method according to claim 17, wherein
the removing the support substrate and the connection layer includes:
grinding a part of the support substrate;
etching a remaining part of the support substrate; and
removing the connection layer.
